(19) United States
(12) Patent Application Publication
(10) Pub. No.: US 2024/0312787 A1
(43) Pub. Date: Sep. 19, 2024

(54) Method of Backgrind Tape Planarization Using Heated Press

(71) Applicant: TEXAS INSTRUMENTS INCORPORATED, Dallas, TX (US)

(72) Inventors: Jose Franco A. Alicante, Baguio City (PH); Roderick S. Balares, Baguio City (PH); Christopher Abenes, Baguio City (PH); Jeniffer Otero Aspuria, Baguio City (PH)

(21) Appl. No.: 18/590,491

(22) Filed: Feb. 28, 2024

Related U.S. Application Data
(60) Provisional application No. 63/451,843, filed on Mar. 13, 2023.

(51) Int. Cl. H01L 21/304; H01L 21/56; H01L 21/683; H01L 23/00

(52) U.S. Cl. CPC H01L 21/304; H01L 21/561; H01L 21/6836; H01L 24/81; H01L 24/13; H01L 2224/13111; H01L 2224/13139; H01L 2224/13144; H01L 2224/13147; H01L 2224/13155; H01L 2224/81

(57) ABSTRACT

Backgrinding a semiconductor wafer includes planarizing backgrind tape without requiring cutting the tape. A semiconductor substrate is provided with an active top surface and a back surface. The active top surface includes a plurality of bumps that connect to devices formed in or on the substrate. A backgrind tape is applied over the top surface of the substrate. The backgrind tape covers the bumps and extends to a periphery of the top surface. The top surface of the substrate is placed so that the backgrind tape is positioned on a chuck table of a backgrind apparatus. Pressure is applied to the back surface of the substrate forcing the backgrind tape against the chuck table. The pressure is removed after a predetermined interval. Backgrinding is performed on the back surface of the substrate to reach a target substrate thickness.

### CROSS-REFERENCE TO RELATED APPLICATIONS

This application claims the benefit of the filing date of U.S. Provisional Patent Application No. 63/451,843, filed Mar. 13, 2023, the disclosure of which is hereby incorporated by reference herein in its entirety.

### BACKGROUND

A wafer, also called a slice or substrate, refers to a thin slice of semiconductor material, such as silicon (Si), used in electronics for the fabrication of integrated circuit (IC) chips and in photovoltaics for wafer-based solar cells. The wafer serves as the substrate for microelectronic devices built in and over the wafer and undergoes microfabrication process stages such as doping or ion implantation, etching, deposition of various materials and photolithographic patterning.

In producing semiconductor devices, a semiconductor wafer is processed in a manufacturing facility to form individual unit semiconductor devices on a surface. Doping, implantation, thermal anneal, formation of dielectrics, and formation of conductors including patterning, plating, sputtering, polishing, and passivation are some of the steps used to fabricate a semiconductor device. Wafer backgrinding, sometimes referred to as wafer thinning or wafer backlapping, is a post-fabrication semiconductor process by which the thickness of a semiconductor wafer is reduced by grinding down the backside of the wafer. The backgrinding process is applied to the backside of the wafer before singulation and packaging to reduce the thickness of the device which also improves the die's thermal properties. After solder balls or bumps are formed on the active top side surface of the chips, a protective adhesive backgrind tape is applied over the top side surface of the wafer. During backgrinding the wafer is held by a chuck table that has a porous center chuck portion, which allows applying a suction to the taped top side surface of the wafer so that the tape protects the bumps from the chuck table. Using a backgrind apparatus, the backside of the wafer is ground to a predetermined thickness (e.g., 100 μm to 200 μm), followed by de-taping, typically cleaning, singulation (dicing), and then bonding the chip to the package substrate.

After backgrinding, scribe lanes are cut between the unit devices, so that the individual semiconductor dies can be separated from one another in a dicing operation after the semiconductor wafer processing is complete.

### SUMMARY

In one arrangement, a method for backgrinding a semiconductor wafer includes planarizing backgrind tape without requiring cutting the tape. A semiconductor substrate is provided with an active top surface and a back surface. The active top surface includes a plurality of bumps that connect to devices formed in or on the substrate. A backgrind tape is applied over the top surface of the substrate. The backgrind tape covers the bumps and extends to a periphery of the top surface. The top surface of the substrate is placed so that the backgrind tape is positioned on a chuck table of a backgrind apparatus. Pressure is applied to the back surface of the substrate forcing the backgrind tape against the chuck table. The pressure is removed after a minimum predetermined interval. Backgrinding is performed on the back surface of the substrate to reach a target substrate thickness.

The minimum interval to apply the pressure may be two minutes in one arrangement. The pressure may be applied using a weight, press, or a planarization table.

Before applying the pressure, an outer surface of the backgrind tape is separated from the active top surface by a first distance in a first region where the bumps are located. The outer surface of the tape is separated from the active top surface by a second distance in a second region near the periphery of the substrate. The first distance is larger than the second distance. A difference between the first distance and the second distance forms a step gap along the periphery of the substrate. When the pressure is applied, the step gap is minimized by planarization of the back surface. The minimized step gap is 5 mm or less in some arrangements. The minimized step gap is at most one-half of an original step gap in some arrangements. The first distance and the second distance may be substantially equal after planarization.

The chuck table is heated above ambient temperature before applying pressure to the back surface. In some arrangements, the chuck table is heated to at least 85° C.

### BRIEF DESCRIPTION OF THE DRAWINGS

Having thus described the invention in general terms, reference will now be made to the accompanying drawings, wherein:

FIGS. 1A-G are cross-section views showing a process for backside grinding of a bumped wafer according to one arrangement.

FIGS. 2A-C are cross-section views showing an alternative process for planarization of a bumped wafer.

FIG. 3 is a graph illustrating changes observed in the step gap in the backgrind tape at the periphery of a bumped wafer.

FIGS. 4A-F are graphs illustrating changes observed in the surface profile of a laminated semiconductor wafer.

FIG. 4G illustrates lines along the surface of the laminated semiconductor wafer referenced by the graphs shown in FIGS. 4A-F.

### DETAILED DESCRIPTION

The present disclosure is described with reference to the attached figures. The figures are not drawn to scale, and they are provided merely to illustrate the disclosure. Several aspects of the disclosure are described below with reference to example applications for illustration. It should be understood that numerous specific details, relationships, and methods are set forth to provide an understanding of the disclosure. The present disclosure is not limited by the illustrated ordering of acts or events, as some acts may occur in different orders and/or concurrently with other acts or events. Furthermore, not all illustrated acts or events are required to implement a methodology in accordance with the present disclosure.

Corresponding numerals and symbols in the different figures generally refer to corresponding parts, unless otherwise indicated. The figures are not necessarily drawn to scale. In the drawings, like reference numerals refer to like elements throughout, and the various features are not necessarily drawn to scale. In the following discussion and in the claims, the terms “including,” “includes,” “having,” “has,” “with,” or variants thereof are intended to be inclusive in a manner similar to the term “comprising,” and thus should be interpreted to mean “including, but not limited to . . . ” Also, the terms “coupled,” “couple,” and/or or “couples” is/are intended to include indirect or direct electrical or mechanical connection or combinations thereof. For example, if a first device couples to or is electrically coupled with a second device that connection may be through a direct electrical connection, or through an indirect electrical connection via one or more intervening devices and/or connections. Elements that are electrically connected with intervening wires or other conductors are considered to be coupled. Terms such as “top,” “bottom,” “front,” “back,” “over,” “above,” “under,” “below,” and such, may be used in this disclosure. These terms should not be construed as limiting the position or orientation of a structure or element but should be used to provide spatial relationship between structures or elements.

The term “semiconductor wafer” is used herein. A semiconductor die refers to a thin slice of material, such as crystalline silicon, that is used to fabricate integrated circuits. A large number of integrated circuits may be created on an active surface of the semiconductor die. Discrete semiconductor devices can be integrated circuits with hundreds or thousands of transistors coupled to form a functional circuit, for example a microprocessor or memory device. The semiconductor device may also be referred to herein as a semiconductor wafer or an integrated circuit (IC) die.

As semiconductor device sizes have decreased, the density of devices on a chip (or die) has increased making chip bonding more difficult. Wafer bumping is the interconnection of choice for many circuits due to lower inductance. The broad term “wafer bumping” as used herein is defined as the process by which solder or a solder alloy, such as gold, copper, or other metal bumps or balls, is applied onto to the devices at the wafer level to be in connection, such as via a redirect layer, with or on the contact pads or bonding pads. There may be an under bump metallization (UBM) layer between the pads and solder balls. In a flip-chip configuration, the solder balls are used to make many connections to package substrates, such as a polymer substrate or a printed circuit board (PCB), where the chip is inverted and attached onto a package substrate via the solder balls. Since the solder balls can form an area array (a “ball grid array” (BGA)), this arrangement provides a high-density for chip interconnections.

The term “semiconductor package” is used herein. A semiconductor package has at least one semiconductor die electrically coupled to terminals and has a package body that protects and covers the semiconductor die. In some arrangements, multiple semiconductor dies can be packaged together. For example, a power metal oxide semiconductor (MOS) field effect transistor (FET) semiconductor device and a second semiconductor device (such as a gate driver die, or a controller die) can be packaged together to from a single packaged electronic device. Additional components such as passive components, such as capacitors, resistors, and inductors or coils, can be included in the packaged electronic device. The semiconductor die is mounted with a package substrate that provides conductive leads. A portion of the conductive leads form the terminals for the packaged device.

In wire bonded integrated circuit packages, bond wires couple conductive leads of a package substrate to bond pads on the semiconductor die. The semiconductor die can be mounted to the package substrate with a device side surface facing away from the substrate and a backside surface facing and mounted to a die pad of the package substrate. In a flip-chip configuration, the solder balls are used to make many connections to package substrates, such as a polymer substrate or a printed circuit board (PCB), where the chip is inverted and attached onto a package substrate via the solder balls.

The semiconductor package may have a package body formed by a thermoset epoxy resin mold compound in a molding process, or by the use of epoxy, plastics, or resins that are liquid at room temperature and are subsequently cured. The package body may provide a hermetic package for the packaged device. The package body may be formed in a mold using an encapsulation process, however, a portion of the leads of the package substrate are not covered during encapsulation, these exposed lead portions form the terminals for the semiconductor package. The semiconductor package may also be referred to as a “integrated circuit package,” a “microelectronic device package,” or a “semiconductor device package.”

A process for manufacturing a semiconductor package uses a semiconductor device that is manufactured from a semiconductor wafer. Materials, such as metal and dielectric layers, are deposited on the wafer and then selectively masking and etching the layers. Many integrated circuit (IC) devices may be fabricated on a single semiconductor wafer by processing arrays of semiconductor die locations across the wafer. Individual semiconductor dies, each having an individual integrated circuit, are then singulated from the wafer. These individual semiconductor dies may then be further processed, such as by mounting the semiconductor die on a leadframe to create a semiconductor package.

Leadframes are formed on a single sheet of metal by stamping or etching. Multiple interconnected leadframes may be formed from a single sheet of substrate, the interconnected leadframes are referred to as a leadframe strip. Tie bars interconnect leads, die attach pads, and other elements of a leadframe to one another as well as to elements of adjacent leadframes in a leadframe strip. A siderail may surround the array of leadframes to provide rigidity and support leadframe elements on the perimeter of the leadframe strip.

Die mounting typically takes place while the leadframes are still integrally connected as a leadframe strip. Semiconductor dies are attached to the leadframe die attach pads, wire bonding electrically connects the dies to lead contacts on the leadframe strip, and a mold compound is applied to cover at least part of the leadframe and semiconductor dies. After the mounting process is completed, the leadframes and mold compound of individual devices are severed (“singulated” or “diced”) with a cutting tool, such as a saw or laser. These singulation cuts separate the leadframe strip into separate semiconductor packages, where each semiconductor package includes a singulated leadframe, at least one semiconductor die, electrical connections between the die and leadframe (such as gold or copper bond wires), and the mold compound that covers at least part of these structures.

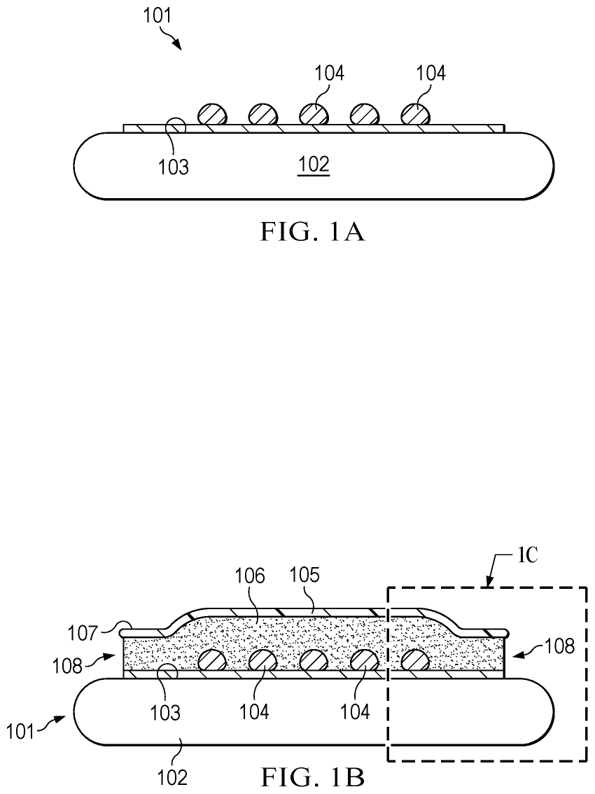

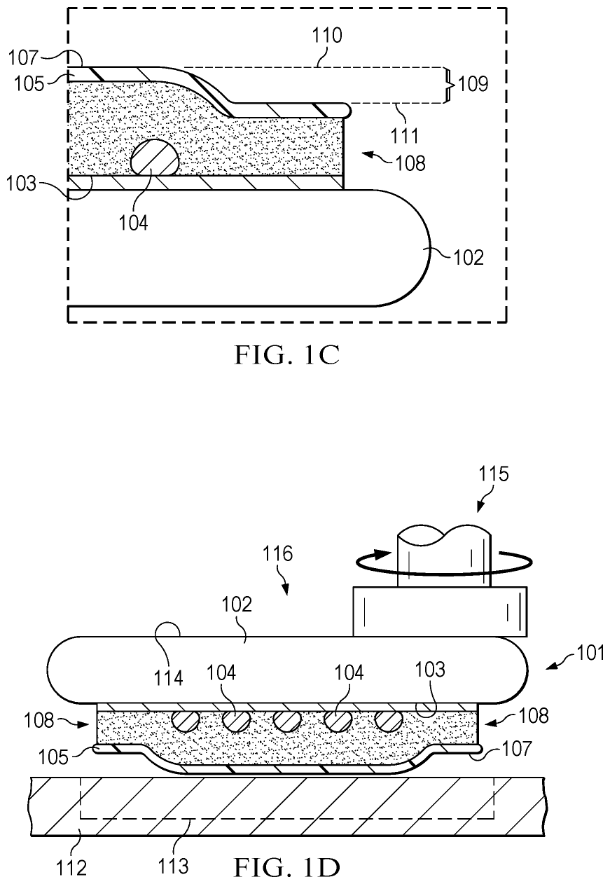

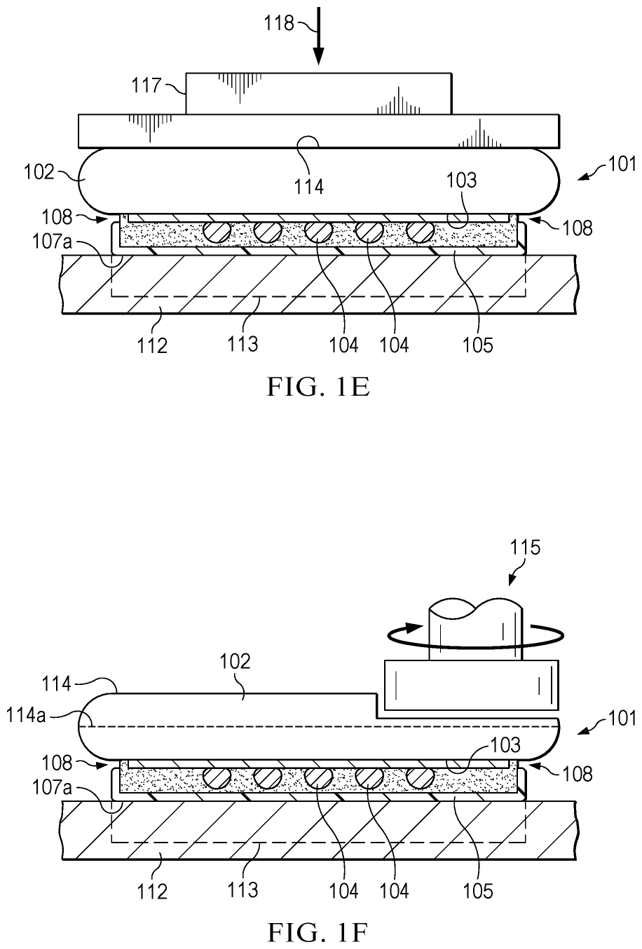

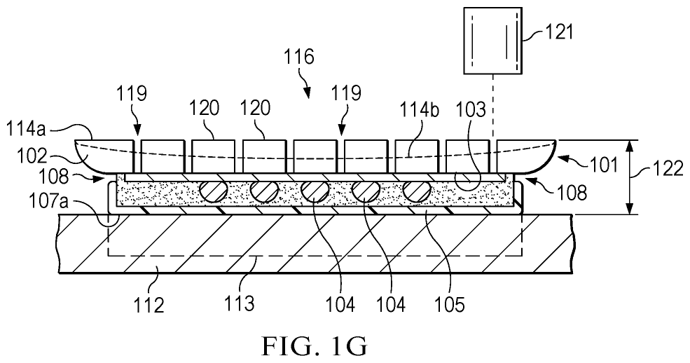

FIGS. 1A-G are cross-section views showing a process for backside grinding of a bumped wafer according to one arrangement. In FIG. 1A, a bumped wafer 101 is provided. The bumped wafer 101 comprises a semiconductor wafer 102, which may be a thin slice of semiconductor substance, such as crystalline silicon, used in electronics for the making of integrated circuits. Semiconductor wafer 102 provides a foundation for building up numerous layers of microscopic structures to create integrated circuits (ICs) through an intricate fabrication process. This highly complex and sophisticated process imprints electronic components and connections layered across an active surface 103 through steps such as: photolithography (using light and masks to project circuit patterns which get etched onto wafer layers), doping (introducing impurities to create distinct n-type and p-type semiconductor areas), deposition (adding material layers through processes such as chemical vapor deposition), and etching (removing selected portions of material to create desired circuit and component geometries).

Wafer bumping is an advanced manufacturing process whereby metal solder balls or bumps 104 are formed on the active surface 103 of semiconductor wafer 102. The wafer bumps 104 provide a connection point between the circuits and components formed on wafer 102 and external structures, such as a substrate or printed circuit board in a device. Wafer bumping is essential to flip-chip or board-level semiconductor packaging. The bumps 104 or balls are formed on the semiconductor wafer 102 before the wafer is diced into individual dies. The bumps 104 may be formed using solder balls of various metals and alloys, such as gold (Au), copper (Cu), Nickel (Ni), tin/silver (SnAg), tin/copper (SnCu), or tin/gold (SnAu), or may be formed as copper (Cu) pillars. The bumps 104 provide an electrical, mechanical and thermal connection path between a semiconductor die and the substrate to which the die is mounted.

FIG. 1B illustrates a backgrind tape 105 applied to active surface 103 on semiconductor wafer 102. Backgrind tape 105 covers bumps 104. In one arrangement, the backgrind tape is an elastic material that is adhesively placed and attached to the bumps 104 to overly the active surface 103 of the wafer 102. The tape 105 may be substantially about the size of the semiconductor wafer 102 so that backgrind tape 105 overlies each of the conductive bumps 104. The backgrind tape 105 may also overlay portions of the wafer 102 without the conductive bumps 104 thereon, such as along a periphery 108 of the active surface 103, to provide protection of the active surface 103. Positioning of the backgrind tape 105 may be accomplished manually and/or by machinery. Backgrind tape 105 may include an adhesive 106 with a backing or outer surface 107. The outer surface 107 or backing is nonadhesive. Backgrind tape 105 may use any adhesive 106 that allows the tape 105 to easily be removed without damaging the wafer 102. The backing or outer surface 107 of backgrind tape 105 may be a polymer material or paper or the like and has sufficient strength so that it will not easily tear.

FIG. 1C shows an expanded portion of the bumped wafer 101 with backgrind tape 105 illustrated in FIG. 1B. As shown in FIG. 1C, uneven lamination of backgrind tape 105 will occur across semiconductor wafer 102 due to variations in the bumped and non-bumped surfaces. This results in an uneven planarity of the outer surface 107 of backgrind tape 105 particularly at the periphery 108 of semiconductor wafer 102 beyond where the bumped area ends. This creates a step gap 109, which is the difference between a first level or plane 110 that covers bumps 104 and a second level or plane 111 at the peripheral non-bumped region 108.

FIG. 1D shows a bumped wafer 101 with backgrind tape 105 of FIG. 1B that has been inverted so that outer surface 107 of backgrind tape 105 is facing down and mounted on a wafer mounting chuck 112. The wafer mounting chuck 112 includes a suction surface 113 on which the outer surface 107 of backgrind tape 105 is attached. The suction surface 113 includes apertures that communicate with a vacuum (not shown) that provides suction at the suction surface 113. The vacuum is integrated with a mounting apparatus to which the wafer mounting chuck 112 is connected. The number of apertures in the suction surface 113 vary depending on the required suction required. Bumped wafer 101 with backgrind tape 105 is placed face down on the wafer mounting chuck 113 to be suctioned thereto.

In particular, the outer surface 107 of backgrind tape 105 sits against the suction surface 113 of the wafer mounting chuck 112 so that the bumped wafer 101 may be held in place for further processing. In the suctioned position, the back surface 114 of the semiconductor wafer 102 faces upward in an exposed position. Typically, such further processing while attached to wafer mounting chuck 112 would include a backgrind process to reduce the semiconductor wafer 102 to a desired thickness by a grinder 115. The grinder 115, as depicted in drawing FIG. 1D, is intended to represent a generic wafer backgrinding tool. In the grinding operation, the bumped wafer 101 may be moved to successive grinding stations having grinding wheels 115 of decreasing grain size and abrasiveness so that the roughness of the back surface 114 is successively decreased. As such, the bumped wafer 101 is thinned to a predetermined thickness.

As illustrated in FIG. 1D, the non-bumped areas on the periphery 108 of semiconductor wafer 102 are not supported by the backgrind tape 105. As a result, if grinder 115 is applied to the back surface 114 without further treatment, then the force exerted by grinder 115 will push the periphery 108 of bumped wafer 101 downward causing semiconductor wafer 102 to flex so that the periphery 108 bows down toward wafer mounting chuck 112. This would cause an uneven amount of material to be removed from the back surface 114 during the backgrinding process. In particular, less material would be removed from the periphery 108 of semiconductor wafer 102 compared to the center region 116 of the back surface 114. Such an uneven thickness of the bumped wafer 101 after backgrinding has been observed to create hairline cracks at the edge of semiconductor wafer 102. Additionally, the uneven thickness creates problems during subsequent processes, such as wafer dicing wherein individual dies are separated from the bumped wafer 101. An uneven back surface 114 causes the variations in laser height for laser dicing and variations in saw depth required for saw dicing.

FIG. 1E illustrates an example arrangement for a process that compensates for the uneven planarity of the outer surface 107 on backgrind tape 105. Before grinder 115 is engaged, a planarization weight 117 is applied to the back surface 114 of the bumped wafer 101 after the wafer is mounted on wafer mounting chuck 112. The planarization weight 117 is forced in a downward direction 118 against back surface 114. This force 118 may be caused by gravity, such as by placing a 10 Kg weight 117 on back surface 114, or by mechanical means, such as a planarization table in a wafer press. In one arrangement, the weight 117 is applied for set period of time, such as for two minutes. The downward force 118 causes backgrind tape 105 to be compressed against and distributed evenly across the suction surface 113 of wafer mounting chuck 112. As a result, the outer surface 107a of backgrind tape 105 takes on a planarized configuration so that backgrind tape 105 provides a consistent amount of support across the active surface 103 of the semiconductor wafer 101. The weight 117 is used for press planarization of the backgrind tape.

An additional advantage of planarizing the backgrind tape 105 using a weight or press is improved vacuum attachment to the suction surface 113 of wafer mounting chuck 112. In some arrangements, the wafer mounting chuck 112 may be heated to facilitate planarization of the backgrind tape 105, such as heating to approximately 85° C. when the bumped wafer 101 is laminated with MY595 backgrind tape.

FIG. 1F illustrates a grinder 115 being applied to back surface 115 of the semiconductor wafer 102 after the planarization process shown in FIG. 1E. The planarized backgrind tape 105 provides consistent support across the active surface 103. As a result, semiconductor wafer 102 does not flex or bend in response to the pressure applied by grinder 115. This allows grinder 115 to remove material from semiconductor wafer equally across back surface 114. Semiconductor wafer 102 may be reduced to a thinner width having a new planar back surface, such as 114a.

FIG. 1G illustrates dicing the bumped wafer 101 after the backgrinding process shown in FIG. 1F wherein perforations 119 are created to divide dies 120 of the bumped wafer 101. In one arrangement, the perforations 119 are formed with a lasing process wherein a laser 121 is used to make cuts in the semiconductor wafer 102. In other arrangements, the perforations 119 may be created using a saw. Each die 120 is implemented as a discrete circuit that is employable in an integrated circuit (IC) chip or other electronic device.

FIG. 1G also illustrates an alternative profile 114b of the back surface of semiconductor wafer 102 that would have been created if backgrind tape 105 was not planarized as illustrated in FIG. 1E. The curved profile 114b shows the thickness of semiconductor wafer 102 thicker at the periphery 108 compared to the center region 116. The profile 114b that results from an unplanarized back surface is not desirable because it would result in dies 120 having different heights in addition to hairline cracks that are generated. By eliminating the uneven thickness at the wafer edge after backgrinding, the total thickness variation (TTV) for the laminated semiconductor wafer is minimized. Instead, the press planarization process provides a relatively constant thickness 122 across the device.

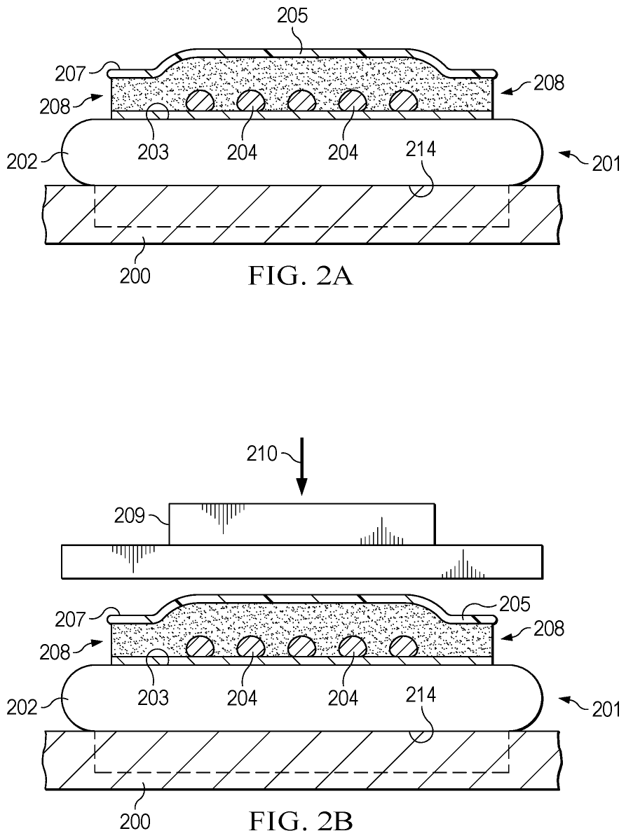

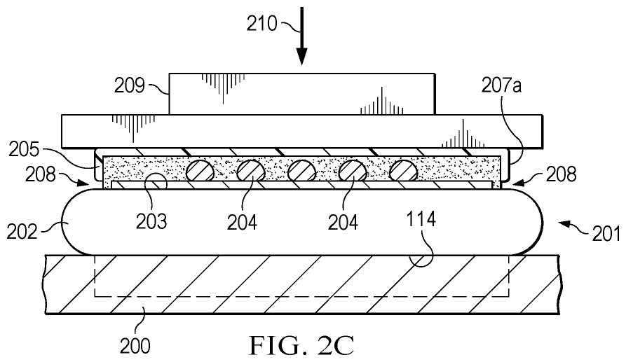

FIGS. 2A-C are cross-section views showing an alternative process for planarization of a bumped wafer. FIG. 2A shows a bumped wafer 201 that has been laminated with backgrind tape 205 similar to the configuration illustrated in FIG. 1B. Instead of mounting this arrangement face down as shown in FIG. 1C, the back surface 214 of the semiconductor wafer 202 is mounted face up on a heated chuck 200. In one configuration, the heated chuck 200 warms the bumped wafer 201 to approximately 85° C. The backgrind tape 205 has an outer surface 207 that is uneven across the active surface 203 due to the distribution of bumps 204. In particular, there is an uneven planarity of the outer surface 207 of backgrind tape 205 particularly at the periphery 208 of semiconductor wafer 202 beyond where the bumped area ends.

FIG. 2B illustrates an alternative process to compensate for the uneven planarity of the outer surface 207 of backgrind tape 205 that differs from the configuration shown in FIG. 1E. Instead, a planarization weight 209 is applied directly to the outer surface 207 of backgrind tape 205. The planarization weight 209 is forced in a downward direction 210 against the outer surface 207. This force 210 may be caused by gravity, such as by placing a 10 Kg weight 209 on the backgrind tape 205, or by mechanical means, such as by applying a planarization table in a wafer press. In one arrangement, the weight 209 is applied for set period of time, such as for two minutes.

As illustrated in FIG. 2C, the downward force 210 causes backgrind tape 205 to be compressed against and distributed evenly across the face of weight 209. As a result, the outer surface 207a of backgrind tape 205 takes on a planarized configuration so that backgrind tape 205 provides a consistent amount of coverage across the active surface 203 of the semiconductor wafer 201. When the weight 209 is removed, the bumped wafer 201 with evenly pressed backgrind tape 205 can then be mounted face down on a wafer mounting chuck 112 and subject to a backgrinding process as shown in FIG. 1F.

In existing semiconductor manufacturing processes, the backgrind tape or lamination covering the bumps on a semiconductor wafer is planarized by fly cutting away a portion of the backgrind tape. For example, a diamond cutting bit may be moved over the backgrind tape while performing a milling type of operation wherein it removes all material that it comes in contact with. The cutting bit is kept at a constant, fixed distance from the chuck table so that only minimal thickness variations will be present after the backgrind tape has been cut. However, the planarization process disclosed herein provides advantages that are available when using the fly cut process. Fly cutting generates waste material that must be cleaned off the backgrind tape, which creates effluent that can cause other problems in the manufacturing facility such as drain clogging due to the removed material. Additionally, the planarization process disclosed herein allows the manufacturer to planarize backgrind tape surfaces without requiring additional machines and materials.

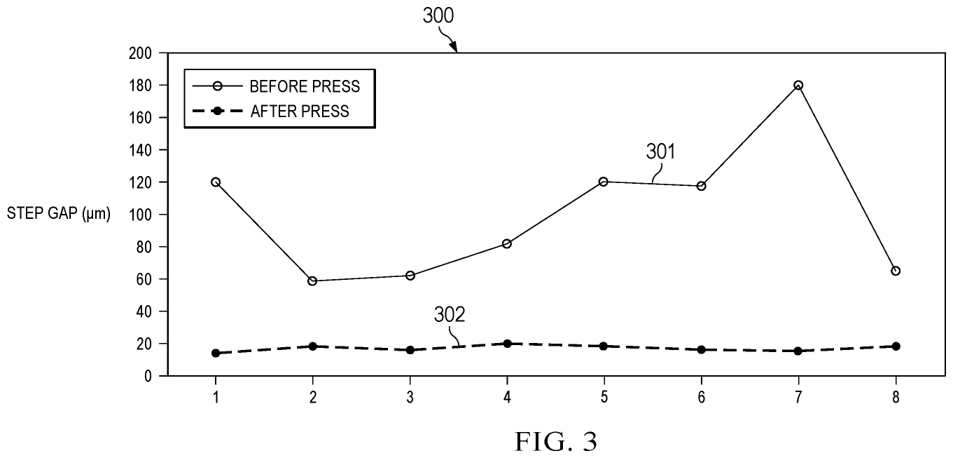

FIG. 3 is a graph 300 illustrating changes observed in the step gap in the backgrind tape at the periphery of a bumped wafer, such as step gap 109 in FIG. 1C, before and after press planarization as described herein. The step gap represents the difference between the highest and lowest elevations of the backgrind tape above the active surface of the semiconductor wafer. Curve 301 represents measurements of the step gap at different points in the backgrind tape lamination along the periphery of a bumped wafer before press planarization. Curve 302 represents measurements of the step gap at corresponding points in the backgrind lamination after press planarization. The press planarization process employed to create the curves 301, 302 in the illustrated example used a 10 Kg weight that was applied to the backgrind tape lamination for two minutes while the bumped semiconductor wafer was mounted on a chuck that was heated to 85° C.

The improvements in planarization are clearly shown by graph 300. The step gap in pre-planarization curve 301 varied from 60 um to 180 um, which suggests that the range of undulation on the surface of the lamination was as much as 120 um. After press planarization, curve 302 shows that the step gap varied between 16 um to 20 um, which suggests that the range of undulation on the surface of the lamination was reduced to 4 um. These observations indicate that the step gap can be improved using press planarization by more than 200% (i.e., the improved step gap is at least one-half of the original step gap). Points 2, 3, and 8 in FIG. 3 show an improvement of approximately 300% (i.e., 60 um/20 um, or the improved step gap is at least one-third of the original). Points 1, 5, and 6 in FIG. 3 show an improvement of approximately 600% (i.e., 120 um/20 um, or at least one-sixth of the original). Point 7 in FIG. 3 further shows an improvement of approximately 900% (i.e., 180 um/20 um).

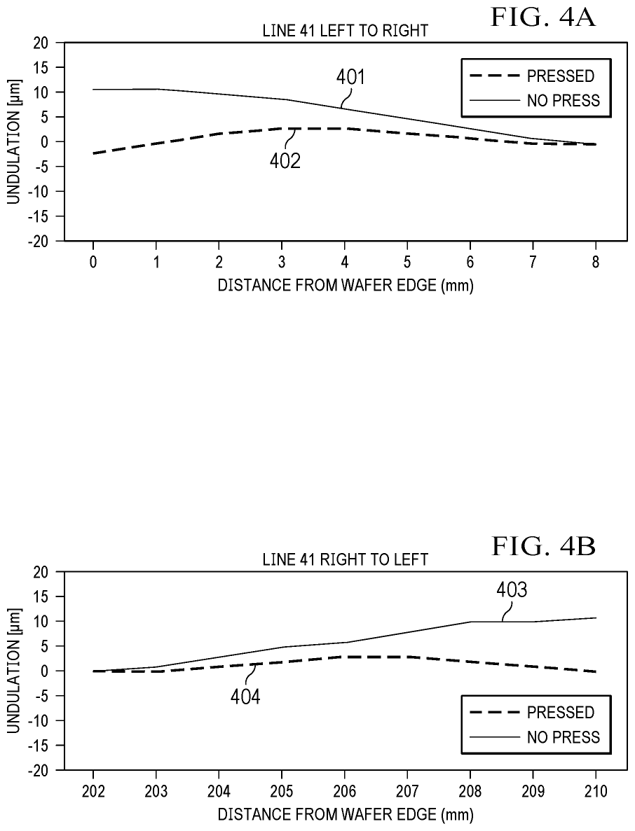

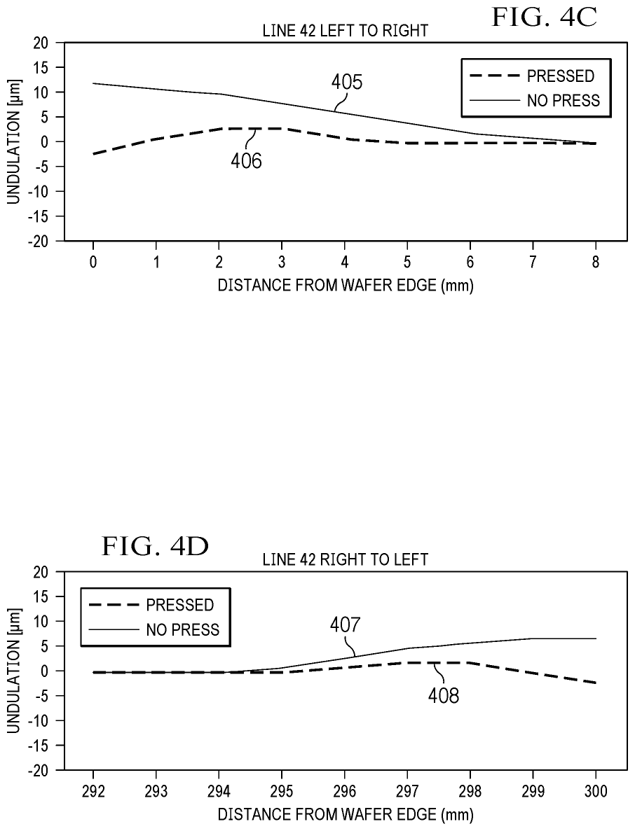

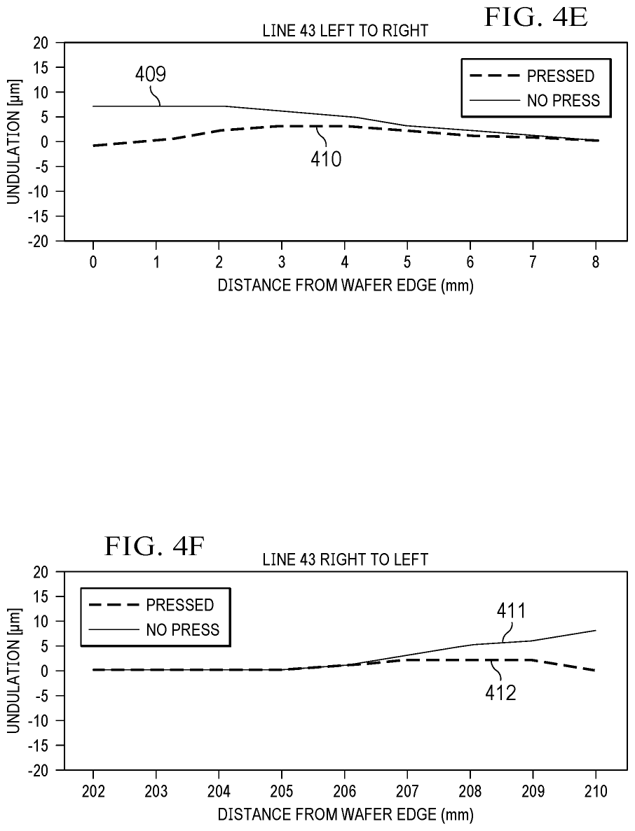

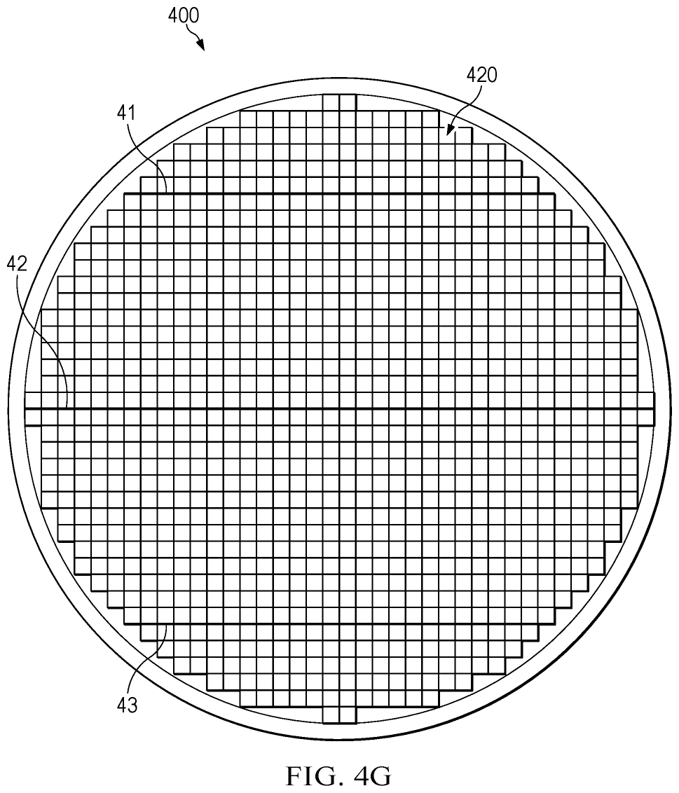

FIGS. 4A-F are graphs illustrating changes observed in the surface profile of a semiconductor wafer before and after the press planarization process. FIG. 4G illustrates a 300 mm semiconductor wafer 400 having a laminated surface 420 that is covered, for example, with a backgrind tape. Three reference lines labeled 41-43 are distributed across surface 420. FIGS. 4A-F illustrate undulation (i.e., offset or deflection from a reference level) in the surface of semiconductor wafer 400 along the periphery of reference lines 41-43 in both the unpressed and pressed conditions.

FIGS. 4A and 4B show changes along opposite ends of reference line 41, which is approximately 210 mm long. Curves 401 and 402 illustrate the undulation of the surface 420 along the first 8 mm at the left end of reference line 41. Curves 403 and 404 illustrate the undulation of the surface 420 along the last 8 mm at the right end of reference line 41. As shown by a visual comparison of the unpressed undulation curves 401, 403 to the post-pressed undulation curves 402, 404, the press planarization process provides a significant improvement to the laminated semiconductor wafer 400. In the unpressed configuration, the level of the laminated surface 420 along line 41 varies by more than 10 mm. Without requiring fly cutting or other removal of the backgrind tape lamination, the press planarization improved undulation on the surface 420 to at or below 5 mm.

FIGS. 4C and 4D show changes along opposite ends of reference line 42, which is approximately 300 mm long. Curves 405 and 406 illustrate the undulation of the surface 420 along the first 8 mm at the left end of reference line 42. Curves 407 and 408 illustrate the undulation of the surface 420 along the last 8 mm at the right end of reference line 42. As shown by a visual comparison of the unpressed undulation curves 405, 407 to the post-pressed undulation curves 406, 408 the press planarization process provides a significant improvement to the laminated semiconductor wafer 400. In the unpressed configuration, the level of the laminated surface 420 along line 42 varies by more than 12 mm. Without requiring fly cutting or other removal of the backgrind tape lamination, the press planarization improved undulation on the surface 420 to less than 5 mm.

FIGS. 4E and 4F show changes along opposite ends of reference line 43, which is approximately 210 mm long. Curves 409 and 410 illustrate the undulation of the surface 420 along the first 8 mm at the left end of reference line 43. Curves 411 and 412 illustrate the undulation of the surface 420 along the last 8 mm at the right end of reference line 43. As shown by a visual comparison of the unpressed undulation curves 409, 411 to the post-pressed undulation curves 410, 412 the press planarization process provides a significant improvement to the laminated semiconductor wafer 400. In the unpressed configuration, the level of the laminated surface 420 along line 43 varies by more than 8 mm. Without requiring fly cutting or other removal of the backgrind tape lamination, the press planarization improved undulation on the surface 420 to less than 4 mm.

In one process for manufacturing a semiconductor package, a semiconductor wafer is provided. The semiconductor wafer has a top surface that includes a plurality of bumps that connect to devices that are formed in or on the semiconductor wafer. The semiconductor wafer also has a back surface opposite the top surface. The process includes applying a backgrind tape over the top surface of the semiconductor wafer. The backgrind tape covers the bumps and extends to a periphery of the top surface. The process includes placing the top surface of the semiconductor wafer so that the backgrind tape is positioned on a chuck table of a backgrind apparatus. The process includes applying a pressure to the back surface of the semiconductor wafer forcing the backgrind tape against the chuck table. The process includes removing the pressure after a predetermined interval. The process includes backgrinding the back surface of the semiconductor wafer.

The process further includes mounting the semiconductor wafer on a die attach pad of a lead frame, electrically connecting the plurality of bumps to the lead frame (such as by using bond wires or solder), covering the semiconductor wafer and at least a portion of the lead frame with a mold compound, and singulating an individual semiconductor package by cutting the mold compound.

The predetermined interval is two minutes in one configuration, which may be a minimum time for applying the pressure. The pressure may be applied using a weight, a planarization table, or a mechanical press.

In some processes, before applying the pressure, an outer surface of the backgrind tape is separated from the active top surface by a first distance in a first region where the bumps are located and is separated from the active top surface by a second distance in a second region near the periphery of the semiconductor wafer, wherein the first distance is larger than the second distance. A difference between the first distance and the second distance forms a step gap along the periphery of the semiconductor wafer. After the pressure is applied, the step gap is minimized by planarization of the back surface. The minimized step gap may be 5 mm or less, or may be at most one-half of an original step gap, or may be at most one-third of an original step gap, or may be at most one-sixth of an original step gap.

Applying pressure to the back surface of the semiconductor wafer causes planarization of an outer surface of the backgrind tape. The outer surface is separated from the active top surface by a first distance in a first region, such as a region where the bumps are located. The outer surface is separated the active top surface by a second distance in a second region, such as near the periphery of the semiconductor wafer. The first distance is substantially equal to the second distance after planarization. The first distance may be within 5 mm of the second distance after planarization.

The process further comprises heating the chuck table above ambient temperature before applying pressure to the back surface. The chuck table may be heated to at least 85° C.

While various examples of the present disclosure have been described above, it should be understood that they have been presented by way of example only and not limitation. Numerous changes to the disclosed examples can be made in accordance with the disclosure herein without departing from the spirit or scope of the disclosure. Modifications are possible in the described embodiments, and other embodiments are possible, within the scope of the claims. Thus, the breadth and scope of the present invention should not be limited by any of the examples described above. Rather, the scope of the disclosure should be defined in accordance with the following claims and their equivalents.

What is claimed is:

1. A process for manufacturing a semiconductor package, comprising:
providing a semiconductor wafer having a top surface that includes a plurality of bumps that connect to devices formed in or on the semiconductor wafer and a back surface opposite the top surface;
applying a backgrind tape over the top surface of the semiconductor wafer, wherein the backgrind tape covers the bumps and extends to a periphery of the top surface;
placing the top surface of the semiconductor wafer so that the backgrind tape is positioned on a chuck table of a backgrind apparatus;
applying a pressure to the back surface of the semiconductor wafer forcing the backgrind tape against the chuck table;
removing the pressure after a predetermined interval; and
backgrinding the back surface of the semiconductor wafer.

2. The process of claim 1, further comprising:
mounting the semiconductor wafer on a die attach pad of a lead frame;
electrically connecting the plurality of bumps to the lead frame;
covering the semiconductor wafer and at least a portion of the lead frame with a mold compound; and
singulating an individual semiconductor package by cutting the mold compound.

3. The process of claim 1, wherein the predetermined interval is two minutes.

4. The process of claim 1, wherein the pressure is applied using a planarization table.

5. The process of claim 1, wherein the pressure is applied using a mechanical press.

6. The process of claim 1, wherein, before applying the pressure, an outer surface of the backgrind tape is separated from the active top surface by a first distance in a first region where the bumps are located and is separated from the active top surface by a second distance in a second region near the periphery of the semiconductor wafer, wherein the first distance is larger than the second distance.

7. The process of claim 6, wherein a difference between the first distance and the second distance forms a step gap along the periphery of the semiconductor wafer.

8. The process of claim 7, wherein, after the pressure is applied, the step gap is minimized by planarization of the back surface.

9. The process of claim 8, wherein the minimized step gap is 5 mm or less.

10. The process of claim 8, wherein the minimized step gap is at most one-half of an original step gap.

11. The process of claim 8, wherein the minimized step gap is at most one-third of an original step gap.

12. The process of claim 8, wherein the minimized step gap is at most one-sixth of an original step gap.

13. The process of claim 1, wherein applying pressure to the back surface of the semiconductor wafer causes planarization of an outer surface of the backgrind tape, wherein the outer surface is separated from the active top surface by a first distance in a first region where the bumps are located and is separated from the active top surface by a second distance in a second region near the periphery of the semiconductor wafer, wherein the first distance is substantially equal to the second distance after planarization.

14. The process of claim 13, wherein the first distance is within 5 mm of the second distance after planarization.

15. The process of claim 1, further comprising:
heating the chuck table above ambient temperature before applying pressure to the back surface.

16. The process of claim 15, wherein the chuck table is heated to at least 85° C.

17. A process of making a semiconductor package, comprising:
providing a semiconductor substrate having an active surface and a back surface opposite the active surface, wherein the active surface includes a plurality of bumps that connect to devices formed in or on the substrate;
laminating a backgrind tape over the active surface of the substrate, wherein the backgrind tape covers the bumps and extends to a periphery of the active surface;
mounting the back surface on a heated chuck;
applying pressure against the backgrind tape using a planarization press to force an outer surface of the backgrind tape into a substantially planar configuration;
placing the active surface of the substrate so that a planarized backgrind tape is positioned on a chuck table of a backgrind apparatus; and
backgrinding the back surface of the substrate to reach a target substrate thickness.

18. The process of claim 17, wherein the pressure is applied for an interval of two minutes.

19. The process of claim 17, wherein, before applying the pressure, the outer surface of the backgrind tape is separated from the active top surface by a first distance in a first region where the bumps are located and is separated from the active top surface by a second distance in a second region near the periphery of the substrate, wherein a difference between the first distance and the second distance forms a step gap along the periphery of the substrate, and wherein the step gap is minimized in the substantially planar configuration.

20. The process of claim 17, further comprising:
heating the chuck table above ambient temperature before applying pressure to the backgrind tape surface, wherein the chuck table is heated to at least 85° C.
